(19) United States
(12) Patent Application Publication
(10) Pub. No.: US 2025/0380580 A1
(43) Pub. Date: Dec. 11, 2025

(54) DISPLAY PANEL AND DISPLAY DEVICE

(71) Applicants: Yungu (Gu’an) Technology Co., Ltd., Langfang (CN); Hefei Visionox Technology Co., Ltd., Hefei (CN)

(72) Inventors: Huanhuan ZHANG, Langfang (CN); Teng PAN, Langfang (CN); PIL-GEUN CHUN, Hefei (CN); Rubo XING, Langfang (CN); Wangfeng XI, Langfang (CN)

(73) Assignees: Yungu (Gu’an) Technology Co., Ltd., Langfang (CN); Hefei Visionox Technology Co., Ltd., Hefei (CN)

(21) Appl. No.: 19/313,767

(22) Filed: Aug. 28, 2025

(30) Foreign Application Priority Data
Aug. 28, 2024 (CN) 202411195277.4

(51) Int. Cl. H10K 59/122; H10K 59/38

(52) U.S. Cl. CPC H10K 59/122; H10K 59/38

(57) ABSTRACT

The embodiments of the present application provide a display panel, a display device, and a method for manufacturing a display panel. The display panel includes: a substrate, an isolation structure, a light-emitting functional layer, and a light conversion layer. The isolation structure is disposed on one side of the substrate and defines a plurality of first isolation openings; the light-emitting functional layer includes a plurality of light-emitting units, at least part of each of the light-emitting units being disposed within the corresponding first isolation opening; and the light conversion layer includes a plurality of light conversion units, at least part of each of the light conversion units being disposed within the corresponding first isolation opening.

### CROSS REFERENCE TO RELATED APPLICATION

The present application claims priority to Chinese Patent Application No. 202411195277.4, titled “DISPLAY PANEL AND DISPLAY DEVICE AND A METHOD FOR MANUFACTURING A DISPLAY PANEL” and filed on Aug. 28, 2024, which is hereby incorporated by references in its entirety.

### FIELD

The present application relates to the field of display devices, and particularly to a display panel, a display device, and a method for manufacturing a display panel.

### BACKGROUND

Liquid crystal display (LCD) panels, organic light-emitting display (OLED) panels, and display panels utilizing light-emitting diode (LED) devices are widely applied in electronic products such as mobile phones, televisions, personal digital assistants, digital cameras, notebook computers, and desktop computers due to their advantages of high image quality, low power consumption, thin form factor, and broad application range.

A light-emitting functional layer and a plurality of light conversion units are provided in the display panel, the light conversion units being configured to adjust color light incident from the light-emitting functional layer. The functional layer adjacent to the light conversion units of the display panel is likely to be separated from the light conversion units, resulting in poor product quality of the display panel.

### SUMMARY

Embodiments of the present application provide a display panel, a display device, and a method for manufacturing a display panel, aiming to improve the product quality of the display panel.

An embodiment of a first aspect of the present application provides a display panel, including:
a substrate;
an isolation structure disposed on one side of the substrate and defining a plurality of first isolation openings;
a light-emitting functional layer including a plurality of light-emitting units, at least part of each of the light-emitting units being disposed within the corresponding first isolation opening; and
a light conversion layer including a plurality of light conversion units, an orthographic projection of each of the light conversion units on the substrate at least partially overlapping an orthographic projection of the corresponding light-emitting unit on the substrate, and at least part of the light conversion unit being disposed within the corresponding first isolation opening.

In the display panel, the display device, and the method for manufacturing a display panel according to the embodiments of the present application, by configuring the orthographic projection of each light conversion unit on the substrate to at least partially overlap the orthographic projection of the corresponding light-emitting unit on the substrate, the light conversion units can adjust the color of light emitted from the light-emitting units, and the display panel can provide richer display effects. By disposing the light conversion units within the corresponding first isolation openings, the surface area of each light conversion unit opposing the isolation structure is increased, thereby preventing, to a certain extent, the separation of the light conversion unit from the functional layer located on the side thereof close to the substrate, and improving the product quality of the display panel.

### BRIEF DESCRIPTION OF THE DRAWINGS

In order to describe the embodiments of the present application more clearly, the drawings required for illustration of the embodiments of the present application will be briefly introduced below. The drawings as described below are only for some of the embodiments of the present application, and other drawings can also be obtained from these drawings.

FIG. 1 is a structural schematic partial cross-sectional view of a display panel according to some embodiments of the disclosure;

FIG. 2 is a structural schematic partial cross-sectional view of a display panel according to some embodiments of the present application;

FIG. 3 is a structural schematic partial cross-sectional view of a light-emitting unit according to some embodiments of the present application;

FIG. 4 is a structural schematic partial cross-sectional view of a display panel according to some embodiments of the present application;

FIG. 5 is a structural schematic partial cross-sectional view of a display panel according to some embodiments of the present application;

FIG. 6 is a structural schematic partial cross-sectional view of a display panel according to some embodiments of the present application;

FIG. 7 is a structural schematic partial cross-sectional view of a display panel according to some embodiments of the present application;

FIG. 8 is a cross-sectional structural schematic diagram of a display panel according to some embodiments of the present application;

FIG. 9 is a structural schematic partial cross-sectional view of a display panel according to some embodiments of the present application;

FIG. 10 is a partial planar structural schematic diagram of a display panel according to some embodiments of the present application;

FIG. 11 is a structural schematic partial cross-sectional view of a display panel according to some embodiments of the present application;

FIG. 12 is a structural schematic partial cross-sectional view of a display panel according to some embodiments of the present application;

FIG. 13 is a structural schematic partial cross-sectional view of a display panel according to some embodiments of the present application; and

FIG. 14 is a schematic flowchart of a method for manufacturing a display panel according to some embodiments of the present application.

### LIST OF REFERENCE SIGNS

1. Substrate;
2. Isolation structure; 21. First portion; 22. Second portion; 23. First isolation opening;
24. Second isolation opening; 25. Recess;
3. Light-emitting functional layer; 31. Light-emitting unit; 32. Charge generation layer; 311. Hole injection layer; 312. First hole transport layer; 313. First auxiliary light-emitting layer; 314. First light-emitting layer; 315. First hole blocking layer; 316. First electron transport layer; 321. Second hole transport layer; 322. Second auxiliary light-emitting layer; 323. Second light-emitting layer; 324. Second hole blocking layer; 325. Second electron transport layer;
4. Light conversion layer; 41. Light conversion unit; 411. First conversion portion; 412. Second conversion portion; 413. Third conversion portion; 42. Light modulation unit;
5. Light-shielding layer; 51. Light-shielding unit; 511. First light-shielding portion; 512. Second light-shielding portion; 513. Third light-shielding portion; 53. First opening; 54. Second opening;
61. First encapsulation layer; 62. Second encapsulation layer; 621. Second encapsulation portion; 63. Third encapsulation layer; 631. First encapsulation portion; 632. Second encapsulation portion; 633. Third encapsulation portion; 65. Fourth encapsulation layer; 651. Fourth encapsulation portion;
7. Filter layer; 71. First filter portion; 72. Light-blocking portion; 73. Planarization layer;
74. Second filter portion;
81. First electrode; 82. Second electrode;
9. Pixel defining layer; 91. Pixel opening.

### DETAILED DESCRIPTION OF THE EMBODIMENTS

Features and exemplary embodiments in various aspects of the present application will be described in detail below. In order to make the embodiments of the present application clearer, the present application will be further described in detail below with reference to the accompanying drawings and specific embodiments. It should be understood that the specific embodiments described herein are merely configured to explain the present application and are not configured to limit the present application. The present application may be implemented without some of these specific details. The following description of the embodiments is merely to provide a better understanding of the present application by illustrating examples of the present application.

It should be noted that, herein, relational terms such as “first” and “second” are only used to distinguish one entity or operation from another entity or operation, and do not necessarily require or imply that such an actual relationship or order exists between these entities or operations. Furthermore, the terms “comprises”, “includes” or any other variant thereof are intended to cover non-exclusive inclusion, and a process, method, object or equipment including a series of elements not only includes those elements, but further includes other elements not explicitly listed, or further includes elements inherent to such process, method, object or equipment. If no more limitations are made, an element limited by “comprising/including . . . ” does not exclude other identical elements existing in the process, the method, the article, or the equipment that includes the element.

It should be understood that in the description of the structure of a component, a layer or region referred as being located “above” or “over” another layer or region may be directly on the other layer or region, or there may be other layers or regions between the layer or region and the other layer or region. Moreover, if the component is turned over, the layer or region is located “below” or “under” the other layer or region.

A light-emitting functional layer, a plurality of light conversion units and a plurality of light-shielding units are provided in a display panel. The light conversion units are configured to adjust color light incident from the light-emitting functional layer, and the light-shielding units are located between adjacent light conversion units. In the display panel, the functional layer adjacent to the light-shielding units and the light conversion units is likely to be separated from the light-shielding units and the light conversion units, resulting in poor product quality of the display panel.

In order to solve the above problem, the embodiments of the present application provide a display panel, a display device, and a method for manufacturing a display panel. Various embodiments of the display panel, the display device and the method for manufacturing the display panel will be described below with reference to the accompanying drawings.

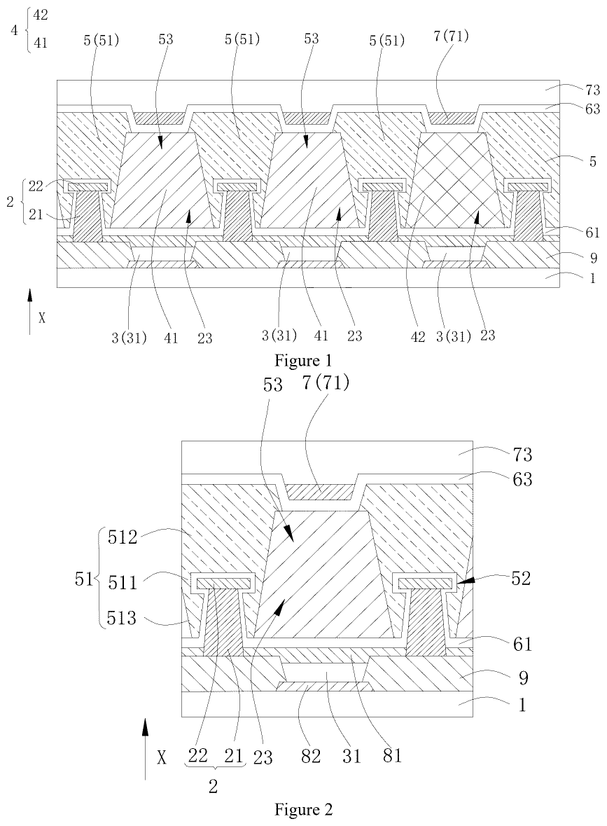

A first aspect of the present application provides a display panel. As shown in FIG. 1 and FIG. 2, the display panel includes a substrate 1, an isolation structure 2, a light-emitting functional layer 3 and a light conversion layer 4. The isolation structure 2 is disposed on one side of the substrate 1, and the isolation structure 2 defines a plurality of first isolation openings 23. The light-emitting functional layer 3 includes a plurality of light-emitting units 31. At least part of each light-emitting unit 31 is disposed within the corresponding first isolation opening 23. The light conversion layer 4 includes a plurality of light conversion units 41. An orthographic projection of each light conversion unit 41 on the substrate 1 at least partially overlaps an orthographic projection of the corresponding light-emitting unit 31 on the substrate 1, and at least part of each light conversion unit 41 is disposed within the corresponding first isolation opening 23.

In the display panel provided in the embodiments of the present application, the substrate 1 may not only provide a supporting force for the isolation structure 2, but may also provide an electrical signal for the light-emitting functional layer 3. The substrate 1 may be configured in various forms. In some embodiments, the substrate 1 may include a base substrate and a drive circuit layer disposed on the base substrate. The base substrate may be a silicon base substrate, or a flexible base substrate, such as polyimide. The drive circuit layer may include a pixel drive circuit, a plurality of stacked conductive connection structures, etc. By way of example, the pixel drive circuit disposed in the drive circuit layer includes a transistor and a storage capacitor. The transistor includes an active layer, a gate, a drain, and a source. The storage capacitor includes a first plate and a second plate. As an example, the gate and the first plate may be located in the same conductive layer, the second plate may be located in another conductive layer, and the drain and the source may be located in still another conductive layer. The drive circuit layer and the light-emitting functional layer 3 may include a plurality of layer structures. Each layer structure may be formed by chemical vapor deposition, evaporation, etc. The direction indicated by the X-axis is a thickness direction of the display panel. The layer structures may be formed starting from the base substrate in sequence along the thickness direction X.

The isolation structure 2 defines a plurality of first isolation openings 23, and adjacent first isolation openings 23 may be separated by the isolation structure 2. At least part of each light-emitting unit 31 is disposed within the corresponding first isolation opening 23, and the number of first isolation openings 23 may be in one-to-one correspondence with the number of light-emitting units 31. The following patents disclose contents related to isolation structures for reference: CN 118251982 A, 202410864269.8, PCT/CN 2024/098407, PCT/CN 2024/102783, PCT/CN 2024/098217, PCT/CN 2024/100935, PCT/CN 2024/102785, PCT/CN 2024/099419, PCT/CN 2024/099072, and CN 116685174 A.

The light-emitting unit 31 may be an organic light-emitting diode (OLED), and the light-emitting unit 31 can emit light outwardly. The plurality of light-emitting units 31 may be configured to emit light of the same color, or the plurality of light-emitting units 31 may be configured to emit light of different colors. Each light-emitting unit 31 may include a first electrode 81, a light-emitting unit 31 and a second electrode 82 which are sequentially stacked in a direction close to the substrate 1. In one embodiment, the light-emitting unit 31 may include a plurality of film layers, for example, an electron injection layer (EIL), an electron transport layer (ETL), a light-emitting material layer, a hole injection layer (HIL) and a hole transport layer (HTL).

Quantum dots of different particle sizes may be provided in the light conversion units 41 as required, to convert incident color light by exciting the quantum dots. The light conversion layer 4 may further include a plurality of light modulation units 42. At least part of each light modulation unit 42 is disposed within the corresponding first isolation opening 23, and the light modulation units 42 and the light conversion units 41 may have the same shape. Compared with the light conversion units 41, the color light entering the light modulation units 42 is emitted from the light modulation units 42 in the same color.

By way of example, the light-emitting units 31 are configured to emit blue light outward, and the plurality of light conversion units 41 include a red light conversion unit 41 capable of converting blue light into red light, a green light conversion unit 41 capable of converting blue light into green light, and a light modulation unit 42 capable of transmitting blue light. The blue light emitted from the light-emitting unit 31 is converted into red light by the red light conversion unit 41 and then emitted, and the blue light emitted from the light-emitting unit 31 is converted into green light by the green light conversion unit 41 and then emitted.

By way of example, the light-emitting units 31 include a blue light-emitting unit 31 for emitting blue light, and a green light-emitting unit 31 for emitting green light. The plurality of light conversion units 41 include a red light conversion unit 41 capable of converting both blue light and green light into red light, a green light conversion unit 41 capable of transmitting green light, and a blue light conversion unit 41 capable of transmitting blue light. The blue light and the green light emitted from the light-emitting units 31 are converted into red light by the red light conversion unit 41 and then emitted.

The display panel provided in the present application may further include a touch layer, a planarization layer, a cover plate, etc. The touch layer may be located on a side of the light conversion layer 4 away from the substrate 1. The planarization layer may be located on the side of the light conversion layer 4 away from the substrate 1, and the cover plate may be located on a side of the planarization layer away from the substrate 1.

In the embodiment according to the present application, by configuring the orthographic projection of each light conversion unit 41 on the substrate 1 to at least partially overlap the orthographic projection of the corresponding light-emitting unit 31 on the substrate 1, the light conversion unit 41 can adjust the color of the light emitted from the light-emitting unit 31, and the display panel can provide richer display effects. At least part of each light conversion unit 41 is disposed within the corresponding first isolation opening 23, and the surface area of the light conversion unit 41 opposing the isolation structure 2 is increased, thereby preventing, to a certain extent, the separation of the light conversion unit 41 from the functional layer located on the side thereof close to the substrate 1, and improving the product quality of the display panel.

In some embodiments, the display panel further includes a first encapsulation layer 61. The first encapsulation layer 61 is disposed on the side of the light-emitting functional layer 3 and the isolation structure 2 away from the substrate 1. The orthographic projection of the first encapsulation layer 61 on the substrate 1 covers at least part of the orthographic projections of the light-emitting units 31 on the substrate 1, and the light conversion layer 4 is disposed on the side of the first encapsulation layer 61 away from the substrate 1.

During manufacturing of the display panel, an isolation structure 2 may be provided on one side of the substrate 1 first; separated light-emitting units 31 are manufactured by means of the isolation structure 2; a first encapsulation layer 61 is provided, which covers the isolation structure 2 and the light-emitting functional layer 3; and then a light conversion layer 4 is provided on the first encapsulation layer 61.

The provision of the first encapsulation layer 61 can improve the barrier performance of the display panel against moisture and oxygen, thereby preventing external moisture and oxygen from entering the light-emitting functional layer 3 and affecting light emission of the light-emitting units 31. The first encapsulation layer 61 can also reduce or avoid the influence of manufacturing operations for the light conversion layer 4 on the previously manufactured light-emitting functional layer 3 and isolation structure 2.

In some embodiments, the light conversion layer 4 is in direct contact with the first encapsulation layer 61, i.e., the light conversion layer 4 may be formed directly on the first encapsulation layer 61, thereby reducing the minimum spacing between the light-emitting units 31 and the corresponding light conversion units 41, shortening a propagation path of light from the light-emitting units 31 to the light conversion units 41, and improving the light extraction efficiency of the display panel.

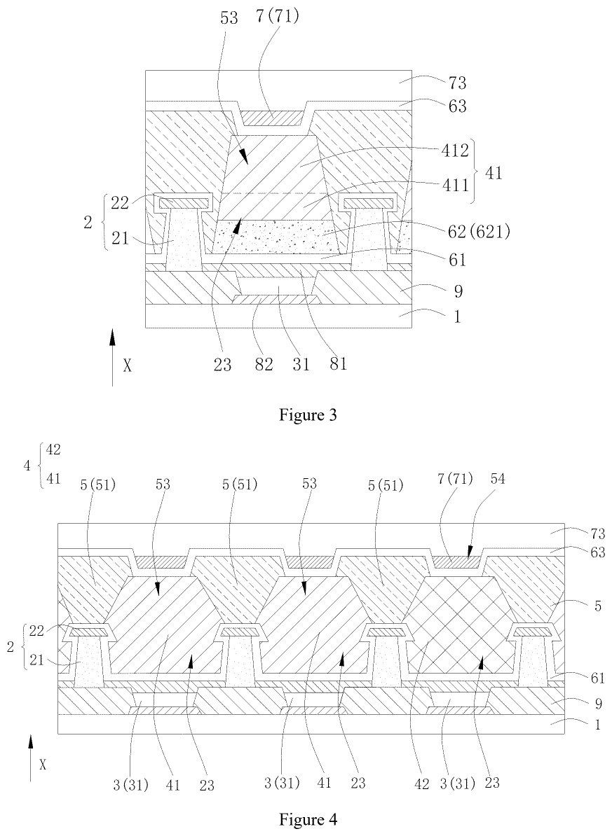

With reference to FIG. 3, in some other embodiments, the display panel further includes a second encapsulation layer 62 disposed between the light conversion layer 4 and the first encapsulation layer 61. The light conversion layer 4 is in direct contact with the second encapsulation layer 62, i.e., the second encapsulation layer 62 may be formed directly on the first encapsulation layer 61, and the light conversion layer 4 may be formed directly on the second encapsulation layer 62. The provision of two encapsulation layers facilitates an improvement in the encapsulation performance of the light-emitting units 31.

In some embodiments, the second encapsulation layer 62 includes a plurality of second encapsulation portions 621. The second encapsulation portions 621 are located within the corresponding first isolation openings 23, and the second encapsulation portions 621 are located between the first encapsulation layer 61 and the light conversion units 41.

The second encapsulation layer 62 and the first encapsulation layer 61 may have different properties to improve the barrier performance of the display panel against moisture and oxygen. One of the first encapsulation layer 61 and the second encapsulation layer 62 is an organic encapsulation layer, and the other is an inorganic encapsulation layer. The inorganic encapsulation layer may be made of an inorganic material such as silicon nitride, silicon oxide, or silicon oxynitride, and may be formed using a chemical vapor deposition (CVD) process. The organic material may be made of resin or an organic polymer material, and may be formed using an inkjet printing (IJP) process.

Compared with the organic encapsulation layer, the inorganic encapsulation layer has better barrier performance against moisture and oxygen. Compared with the inorganic encapsulation layer, the organic encapsulation layer has better flexibility and film-forming properties. By encapsulating the light-emitting functional layer 3 with both the organic encapsulation layer and the inorganic encapsulation layer, the overall barrier performance of the display panel against moisture and oxygen is improved. Compared with the inorganic encapsulation layer, the organic encapsulation layer has better flexibility. In one embodiment, the first encapsulation layer 61 is an inorganic encapsulation layer, and the second encapsulation layer 62 is an organic encapsulation layer, such that each second encapsulation portion 621 can planarize the first encapsulation layer 61. As a result, the surface of the second encapsulation portion 621 away from the substrate 1 becomes flat, facilitating the manufacturing of the light conversion units 41 of a desired structure.

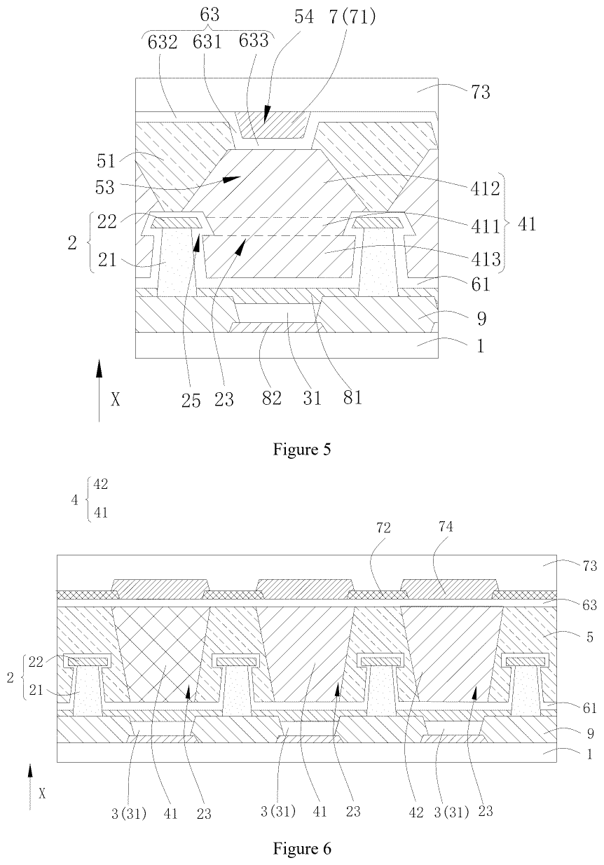

With reference to FIG. 4 and FIG. 5, in some embodiments, the light conversion unit 41 includes a first conversion portion 411. The first conversion portion 411 is disposed within the corresponding first isolation opening 23.

The first conversion portion 411 being disposed within the corresponding first isolation opening 23 increases the surface area of the first conversion portion 411 opposing the isolation structure 2, thereby preventing, to a certain extent, the separation of the light conversion unit 41 from the functional layer located on the side thereof close to the substrate 1.

The light conversion unit 41 may further include other portions disposed outside the first isolation opening 23, which may be disposed on the side of the first conversion portion 411 away from or close to the substrate 1. In some embodiments, the light conversion unit 41 includes a second conversion portion 412. The second conversion portion 412 is stacked on the side of the first conversion portion 411 away from the substrate 1, and the second conversion portion 412 is located outside the first isolation opening 23.

By the second conversion portion 412 being located on the outside of the first isolation opening 23, it can be understood that a distance from the surface of the second conversion portion 412 close to the substrate 1 to the substrate 1 is greater than a distance from a port of the first isolation opening 23 away from the substrate 1 to the substrate 1. The light conversion unit 41 is located partially within the first isolation opening 23 and partially outside the first isolation opening 23, thereby increasing the size of the light conversion unit 41 and facilitating light conversion by the light conversion unit 41.

In some embodiments, the orthographic projection of the light-emitting unit 31 on the substrate 1 is located within the orthographic projection of the light conversion unit 41 on the substrate 1.

By the orthographic projection of the light-emitting unit 31 on the substrate 1 being located within the orthographic projection of the light conversion unit 41 on the substrate 1, it is meant that the light conversion unit 41 covers the side of the light-emitting unit 31 away from the substrate 1, thereby increasing the amount of light emitted from the light-emitting unit 31 into the light conversion unit 41, and thus increasing the amount of light emitted from the light conversion unit 41.

In some embodiments, the orthographic projection of the second conversion portion 412 on the substrate 1 at least partially overlaps the orthographic projection of the isolation structure 2 on the substrate 1.

By the orthographic projection of the second conversion portion 412 on the substrate 1 at least partially overlapping the orthographic projection of the isolation structure 2 on the substrate 1, it is meant that at least part of the second conversion portion 412 is disposed opposite the isolation structure 2 in a first direction X, thereby increasing the area of the orthographic projection of the second conversion portion 412 on the substrate 1, and facilitating an improvement in the light conversion efficiency of the light conversion unit 41. Moreover, the surface area of the second conversion portion 412 opposing the isolation structure 2 can be increased, thereby preventing, to a certain extent, the separation of the light conversion unit 41 from the functional layer located on the side thereof close to the substrate 1, and improving the product quality of the display panel.

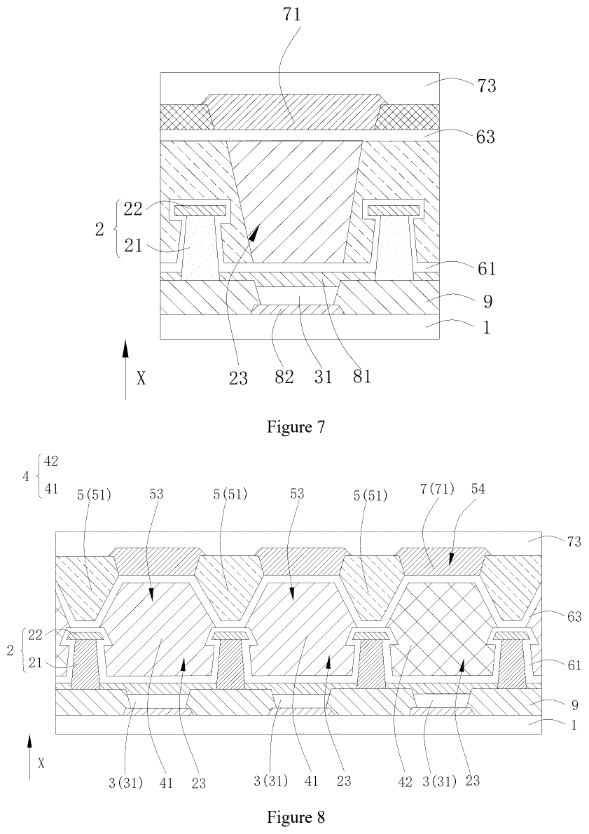

With reference to FIG. 6 and FIG. 7, in some embodiments, the orthographic projection on the substrate 1 of the surface of the second conversion portion 412 close to the substrate 1 is located within the orthographic projection on the substrate 1 of the surface of the second conversion portion 412 away from the substrate 1.

In a direction from the substrate 1 to the light-emitting unit 31, the size of a cross-section of the second conversion portion 412 may gradually increase. For example, the second conversion portion 412 has a trapezoidal cross-section, a length of a bottom base of the trapezoid close to the substrate 1 being less than a length of a top base of the trapezoid away from the substrate 1. By configuring the orthographic projection on the substrate 1 of the surface of the second conversion portion 412 close to the substrate 1 to be located within the orthographic projection on the substrate 1 of the surface of the second conversion portion 412 away from the substrate 1, the emission of the converted light from the second conversion portion 412 is facilitated, improving the light conversion efficiency of the light conversion unit.

With reference to FIG. 4 and FIG. 5, in some embodiments, the orthographic projection of the first conversion portion 411 on the substrate 1 is located within the orthographic projection of the second conversion portion 412 on the substrate 1.

By configuring the orthographic projection of the first conversion portion 411 on the substrate 1 to be located within the orthographic projection of the second conversion portion 412 on the substrate 1, the second conversion portion 412 can form a cap structure with respect to the first conversion portion 411, to facilitate the fixation of the light conversion unit 41 within the first isolation opening 23, thereby preventing, to a certain extent, the separation of the light conversion unit 41 from the functional layer located on the side thereof close to the substrate 1, and improving the product quality of the display panel.

In some embodiments, the light conversion unit 41 includes a third conversion portion 413. The third conversion portion 413 is disposed on a side of the first conversion portion 411 close to the substrate 1. The third conversion portion 413 is disposed within the first isolation opening 23. The orthographic projection of the first conversion portion 411 on the substrate 1 is located within an orthographic projection of the third conversion portion 413 on the substrate 1.

The orthographic projection of the first conversion portion 411 on the substrate 1 is located within the orthographic projection of the third conversion portion 413 on the substrate 1, and in the direction from the substrate 1 to the light-emitting unit 31, the part of the light conversion unit 41 located within the first isolation opening 23 has a structure that is larger at the bottom and smaller at the top, and the disengagement of the light conversion unit 41 from the first isolation opening 23 can thus be prevented to a certain extent.

When the orthographic projection of the first conversion portion 411 on the substrate 1 is located within the orthographic projection of the second conversion portion 412 on the substrate 1, the light conversion unit 41 has a structure that is larger at two ends and smaller in the middle. The third conversion portion 413 can prevent the disengagement of the light conversion unit 41 in a direction from the substrate 1 to the light-emitting functional layer 3, and the second conversion portion 412 can prevent the disengagement of the light conversion unit 41 in a direction from the light-emitting functional layer 3 to the substrate 1, thereby ensuring the structural stability of the light conversion unit 41 within the isolation structure 2.

In some embodiments, the orthographic projection of the third conversion portion 413 on the substrate 1 is located within the orthographic projection of the second conversion portion 412 on the substrate 1.

Since the orthographic projection of the third conversion portion 413 on the substrate 1 is located within the orthographic projection of the second conversion portion 412 on the substrate 1, the second conversion portion 412 has a larger light-emitting area.

In some embodiments, the isolation structure 2 includes a first portion 21 and a second portion 22 that are stacked. The first portion 21 is disposed on a side of the second portion 22 close to the substrate 1, and an orthographic projection of the first portion 21 on the substrate 1 is located within an orthographic projection of the second portion 22 on the substrate 1.

The isolation structure 2 defines first isolation openings 23 to define an arrangement range of the light-emitting functional layer 3. The isolation structure 2 includes a first portion 21 and a second portion 22 that are stacked. The orthographic projection of the first portion 21 on the substrate 1 is located within the orthographic projection of the second portion 22 on the substrate 1, and an end of the isolation structure 2 away from the substrate 1 has a larger cross-sectional area than an end of the isolation structure 2 close to the substrate 1. In a direction (direction X) from the isolation structure 2 to the substrate 1, the second portion 22 shields the entire first portion 21.

During the manufacturing of the light-emitting units 31, a light-emitting material A used for manufacturing the light-emitting units 31 may cover the isolation structure 2 by means of evaporation technology. Since the second portion 22 shields the first portion 21, the light-emitting material A used for manufacturing the light-emitting units 31 has a large drop at an edge of the second portion 22, and it is unlikely to connect the light-emitting material A deposited into the first isolation opening 23 and the light-emitting material A deposited on the second portion 22. Accordingly, breakage occurs, and pieces of light-emitting material A spaced apart from each other are formed in adjacent first isolation openings 23. The light-emitting material A deposited on the second portion 22 may be removed as required. Compared with the related art in which the light-emitting functional layer 3 is manufactured by evaporation using a mask, in the present application, by providing the first portion 21 and the second portion 22, the light-emitting units 31 located within the first isolation openings 23 can be manufactured without using a metal mask, thereby eliminating the cost of manufacturing the metal mask. Compared with manufacturing the light-emitting functional layer 3 by evaporation by manufacturing a high-precision metal mask, directly manufacturing the high-precision isolation structure 2 is easier to implement. As a result, the requirements for the manufacturing process of the display panel provided in the present application are low, and the manufactured display panels have good consistency. The light-emitting material A may be a complex containing an indium element.

By configuring the isolation structure 2 to include the first portion 21 and the second portion 22, and by configuring the orthographic projection of the first portion 21 on the substrate 1 to be located within the orthographic projection of the second portion 22 on the substrate 1, the light-emitting functional layer 3 can be manufactured without using a metal mask, thereby reducing the requirements for the manufacturing process of the structure of the display panel provided in the present application and achieving good consistency of the manufactured display panels. The first isolation openings 23 are defined by the first portion 21 and the second portion 22. The second portion 22 shields the first portion 21, and wall surfaces of the first isolation openings 23 are configured to be non-planar, thereby increasing the surface area of the first conversion portion 411 opposing the isolation structure 2.

In some embodiments, the third conversion portion 413 is located on the side of the second portion 22 close to the substrate 1, and the orthographic projection of the third conversion portion 413 on the substrate 1 overlaps the orthographic projection of the second portion 22 on the substrate 1.

The third conversion portions 413 of adjacent light conversion units 41 are separated by the first portion 21, and the first conversion portions 411 of the adjacent light conversion units 41 may be separated by the second portion 22. The orthographic projection of the third conversion portion 413 on the substrate 1 overlaps the orthographic projection of the second portion 22 on the substrate 1, and the third conversion portion 413 can be restrained by the second portion 22, thereby preventing or reducing, to a certain extent, the disengagement of the light conversion unit 41 from the first isolation opening 23. In one embodiment, an edge of the third conversion portion 413 is disposed opposite the second portion 22 in the first direction X.

In some embodiments, the area of the orthographic projection on the substrate 1 of the surface of the first portion 21 away from the substrate 1 is less than the area of the orthographic projection on the substrate 1 of the surface of the second portion 22 close to the substrate 1. The surface of the first portion 21 defining the first isolation opening 23 and the surface of the second portion 22 close to the substrate 1 define a recess 25. At least part of the third conversion portion 413 is located within the recess 25.

Since the area of the orthographic projection on the substrate 1 of the surface of the first portion 21 away from the substrate 1 is less than the area of the orthographic projection on the substrate 1 of the surface of the second portion 22 close to the substrate 1, a step is formed from the surface of the first portion 21 defining the first isolation opening 23 to the surface of the second portion 22 defining the first isolation opening 23, and the surface of the first portion 21 defining the first isolation opening 23 and the surface of the second portion 22 close to the substrate 1 define a recess 25. The recess 25 is an area that is recessed in a direction away from the center of the first isolation opening 23. By configuring at least part of the third conversion portion 413 to be located within the recess 25, the third conversion portion 413 is prevented from disengaging from the first isolation opening 23.

In some embodiments, the display panel further includes a light-shielding layer 5. The light-shielding layer 5 includes a plurality of light-shielding units 51. At least part of each light-shielding unit 51 defines a first opening 53. The first opening 53 is in communication with the corresponding first isolation opening 23, and at least part of the light conversion unit 41 is located within the first opening 53.

The light-shielding unit 51 may be made of an opaque material, such that the light conversion unit 41 is located within the first opening 53, thereby preventing or reducing, to a certain extent, the mixing of light emitted from adjacent light conversion units 41.

In some embodiments, the orthographic projection of the first opening 53 on the substrate 1 overlaps the orthographic projection of the first isolation opening 23 on the substrate 1, and at least part of the light conversion unit 41 may extend from the first isolation opening 23 to the first opening 53 in the first direction X, thereby facilitating the transmission and emission of light through the light conversion unit 41.

In some embodiments, the orthographic projection of the light-shielding unit 51 on the substrate 1 overlaps the orthographic projection of the isolation structure 2 on the substrate 1.

The orthographic projection of the light-shielding unit 51 on the substrate 1 may cover the orthographic projection of the isolation structure 2 on the substrate 1, i.e., at least part of the light-shielding unit 51 is disposed on the side of the isolation structure 2 away from the substrate 1. When the light-shielding units 51 are configured to have the same size, at least part of the light-shielding unit 51 is disposed on the side of the isolation structure 2 away from the substrate 1, thereby preventing or reducing the occupation of the space, on the side of the light-emitting unit 31 away from the substrate 1, by the light-shielding unit 51, and increasing the amount of light emitted from the light-emitting unit 31 into the light conversion unit 41.

In some embodiments, the orthographic projection of the first opening 53 on the substrate 1 is located within the orthographic projection of the first isolation opening 23 on the substrate 1.

A cross-sectional area of the first opening 53 may be greater than the cross-sectional area of the first isolation opening 23, and the light conversion unit 41 disposed within the first opening 53 may have a larger size, thereby facilitating an improvement in the light conversion efficiency of the light conversion unit 41.

With reference to FIG. 1 and FIG. 2, in some other embodiments, the orthographic projection of the first opening 53 on the substrate 1 is located within the orthographic projection of the first isolation opening 23 on the substrate 1.

The cross-sectional area of the first opening 53 may be less than the cross-sectional area of the first isolation opening 23, and part of the light-shielding unit 51 can shield one side of the light-emitting unit 31, thereby reducing or preventing light emitted from the light-emitting unit 31 from being directly emitted without passing through the light conversion unit 41.

In some embodiments, the light-shielding unit 51 includes a first light-shielding portion 511 and a second light-shielding portion 512. The first light-shielding portion 511 is disposed on a side of the second light-shielding portion 512 close to the substrate 1. The first light-shielding portion 511 is disposed within the first isolation opening 23, and the second light-shielding portion 512 is located on the side of the first isolation opening 23 away from the substrate 1.

The first isolation opening 23 is defined by the first portion 21 and the second portion 22. The second portion 22 shields the first portion 21, and a wall surface of the first isolation opening 23 is configured to be non-planar, thereby increasing the surface area of the first light-shielding portion 511 opposing the isolation structure 2. In addition, since part of the light-shielding unit 51 is located within the first isolation opening 23, and another part thereof is located outside the first isolation opening 23, the separation of the light-shielding unit 51 from the functional layer located on the side thereof close to the substrate 1 is prevented to a certain extent.

In some embodiments, an orthographic projection on the substrate 1 of the surface of the second light-shielding portion 512 close to the substrate 1 at least partially overlaps the orthographic projection of the isolation structure 2 on the substrate 1.

By the orthographic projection of the second light-shielding portion 512 on the substrate 1 at least partially overlapping the orthographic projection of the isolation structure 2 on the substrate 1, it is meant that at least part of a surface of the second light-shielding portion 512 close to the substrate 1 is disposed opposite the isolation structure 2 in the first direction X, thereby increasing the surface area of the second light-shielding portion 512 opposing the isolation structure 2, preventing or reducing, to a certain extent, the separation of the light-shielding unit 51 from the functional layer located on the side thereof close to the substrate 1, and improving the product quality of the display panel.

In some embodiments, the light-shielding unit 51 has a receiving cavity 52, and at least part of the isolation structure 2 is received within the receiving cavity 52.

The light-shielding unit 51 may be disposed on an outer side of the second portion 22, to receive the second portion 22 within the receiving cavity 52. At least part of the isolation structure 2 is received within the receiving cavity 52, thereby reducing or preventing the mixing of light emitted from adjacent light conversion units 41 through the isolation structure 2, for example, through the second portion 22.

In some embodiments, at least part of the first portion 21 is received within the receiving cavity 52.

At least part of the first portion 21 being received within the receiving cavity 52 increases the area of the light-shielding unit 51 disposed between adjacent light conversion units 41, thereby increasing the light-shielding area of the light-shielding unit 51 between adjacent light conversion units 41.

In some embodiments, the same light-shielding unit 51 is located within adjacent first isolation openings 23, respectively, and the structural stability of the parts of the light-shielding unit 51 that extend into the adjacent first isolation openings 23 can be improved. By disposing the light-shielding unit 51 and the light-emitting unit 31 together within the first isolation opening 23, the pixel density of the display panel can be increased.

In some embodiments, the first light-shielding portions 511 located within the same first isolation opening 23 surround the light conversion unit 41.

The first light-shielding portions 511 surround the light conversion unit 41, to shield the periphery of the light conversion unit 41.

In one embodiment, the isolation structure 2 is mesh-like, and the light-shielding layer 5 is mesh-like. The light conversion units 41 are located within mesh openings of the mesh-like isolation structure 2. The light conversion units 41 are located within mesh openings of the mesh-like light-shielding layer 5. The first light-shielding portions 511 are in the form of rings spaced apart from each other. The ring-shaped first light-shielding portions 511 are respectively disposed around the corresponding light conversion units 41.

With reference to FIG. 4 and FIG. 5, in some embodiments, at least part of the light-shielding unit 51 defines a second opening 54, and the first opening 53 is in communication with the corresponding second opening 54. The display panel further includes a first filter layer 7. The first filter layer 7 includes a plurality of first filter portions 71, the first filter portions 71 are disposed on the side of the light conversion units 41 away from the substrate 1, and at least part of each first filter portion 71 is disposed within the corresponding second opening 54.

The first filter portions 71 may be made of a filter material, and each first filter portion 71 allows only light of a single color to pass through. The first filter portions 71 can filter out stray light, thereby improving the display effect of the display panel. By way of example, the plurality of first filter portions 71 may include a red filter portion, a blue filter portion and a green filter portion. The red filter portion corresponds to the red light conversion unit and allows only red light to pass through. The green filter portion corresponds to the green light conversion unit and allows only green light to pass through. The blue filter portion corresponds to the light modulation unit and allows only blue light to pass through.

At least part of the first filter portion 71 is disposed within the second opening 54, and the light-shielding unit 51 can avoid or reduce the mixing of light emitted from adjacent first filter portions 71, thereby improving the display effect of the display panel. One light-shielding unit 51 may have a light-shielding effect on both the light conversion unit 41 and the first filter portion 71, thereby eliminating the need to manufacture two light-shielding members for shielding the light conversion unit 41 and the first filter portion 71, respectively.

In some embodiments, the orthographic projection of the first filter portion 71 on the substrate 1 at least partially overlaps the orthographic projection of the light conversion unit 41 on the substrate 1.

The orthographic projection of the first filter portion 71 on the substrate 1 at least partially overlaps the orthographic projection of the light conversion unit 41 on the substrate 1, and light emitted through the light conversion unit 41 can enter the first filter portion 71.

In some embodiments, an area of an orthographic projection on the substrate 1 of a surface of the first filter portion 71 away from the substrate 1 is greater than an area of an orthographic projection on the substrate 1 of a surface of the first filter portion 71 close to the substrate 1.

An end of the first filter portion 71 away from the substrate 1 is larger than an end of the first filter portion 71 close to the substrate 1, thereby increasing the area through which light is emitted from the first filter portion 71.

With reference to FIG. 8, in some embodiments, the display panel includes a third encapsulation layer 63. The third encapsulation layer 63 is located between the first filter portions 71 and the light conversion units 41.

The third encapsulation layer 63 may be an inorganic encapsulation layer. The provision of the third encapsulation layer 63 between the first filter portions 71 and the light conversion units 41 reduces or prevents, to a certain extent, the influence of the step of manufacturing the first filter portions 71 on the manufactured light conversion units 41, and prevents or reduces the mutual influence between the material for forming the first filter portions 71 and the material for forming the light conversion units 41. The third encapsulation layer 63 may be of the same material as the first encapsulation layer 61, to simplify the types of manufacturing material to be stored.

In some embodiments, the light-shielding units 51 are located on the side of the third encapsulation layer 63 away from the substrate 1, and the third encapsulation layer 63 can prevent moisture, etc., from entering the isolation structure 2 from the light-shielding units 51.

In some embodiments, the third encapsulation layer 63 is disposed to space the light-shielding units 51 apart from the light conversion units 41, such that the third encapsulation layer 63 can prevent moisture, etc., from entering the light conversion units 41 from the light-shielding units 51. The third encapsulation layer 63 can also prevent the process of forming the light-shielding units 51 from affecting the manufactured light conversion units 41.

In some embodiments, the plurality of first filter portions 71 are spaced apart from each other, and part of each light-shielding unit 51 is located between adjacent first filter portions 71.

The light-shielding unit 51 may be disposed not only to space adjacent light conversion units 41 apart from each other, but also to space adjacent first filter portions 71 apart from each other, and the light-shielding unit 51 can shield light at a large angle, thereby alleviating the crosstalk problem of light emitted at a large angle between adjacent first filter portions 71. Compared with a solution where a light-shielding member is disposed between adjacent light conversion units 41 and another light-shielding member is disposed between adjacent first filter portions 71, part of the light-shielding unit 51 being located between adjacent first filter portions 71 only requires the light-shielding layer 5 to be manufactured, simplifying the process.

In some embodiments, each first filter portion 71 protrudes in a direction away from the substrate 1 relative to a surface of the corresponding light-shielding unit 51 away from the substrate 1, and an edge of the first filter portion 71 overlaps and is connected to the surface of the light-shielding unit 51 away from the substrate 1.

The first filter portion 71 protruding in the direction away from the substrate 1 relative to the surface of the light-shielding unit 51 away from the substrate 1 increases the area through which light is emitted from the first filter portion 71. The edge of the first filter portion 71 overlapping and being connected to the surface of the light-shielding unit 51 away from the substrate 1 increases the area of contact between the first filter portion 71 and the light-shielding unit 51, improving the relative stability of the two.

The display panel further includes a planarization layer 73. The planarization layer 73 covers a side of the first filter portions 71 away from the substrate 1, and a side of the light-shielding units 51 away from the substrate 1, to planarize the light-shielding layer 5 and the first filter layer 7 to facilitate the manufacturing of other functional layers. The other functional layers may be a cover plate. In one embodiment, the planarization layer 73 is a layer structure manufactured using an optically clear adhesive (OCA).

With reference to FIG. 4 and FIG. 5, in some embodiments, the light-shielding units 51 are located on a side of the third encapsulation layer 63 close to the substrate 1, and the third encapsulation layer 63 can prevent moisture, etc., from entering the light-shielding units 51.

In some embodiments, the third encapsulation layer 63 is disposed to space the light-shielding units 51 apart from the first filter portions 71, and the third encapsulation layer 63 can isolate the material for manufacturing the light-shielding units 51 from the material for manufacturing the first filter portions 71, thereby preventing the process for forming the first filter portions 71 from affecting the manufactured light-shielding units 51.

In one embodiment, a first encapsulation portion 631 of the third encapsulation layer 63 is located between the adjacent first filter portion 71 and light-shielding unit 51, and the first encapsulation portion 631 can space the first filter portion 71 apart from the light-shielding unit 51, thereby mitigating the influence of the process for manufacturing the first filter portion 71 on the light-shielding unit 51.

In some embodiments, the third encapsulation layer 63 includes a second encapsulation portion 632. An orthographic projection of the second encapsulation portion 632 on the substrate 1 at least partially overlaps the orthographic projection of the light-shielding unit 51 on the substrate 1. The surface of the first filter portion 71 away from the substrate 1 is in the same reference plane as a surface of the second encapsulation portion 632 away from the substrate 1.

The surface of the first filter portion 71 away from the substrate 1 being in the same reference plane as the surface of the second encapsulation portion 632 away from the substrate 1 facilitates the provision of other functional layers on the side of the filter layer 7 away from the substrate 1.

In some embodiments, a third encapsulation portion 633 of the third encapsulation layer 63 covers the side of the light conversion unit 41 away from the substrate 1. The first encapsulation portion 631 connects the second encapsulation portion 632 and the third encapsulation portion 633. The third encapsulation portion 633 and the first encapsulation portion 631 define a groove for receiving the first filter portion 71.

The third encapsulation layer 63 may be manufactured by chemical vapor deposition. Since the light-shielding unit 51 protrudes relative to the light conversion unit 41, the manufactured third encapsulation layer 63 can provide a step between the light-shielding unit 51 and the light conversion unit 41 to form the groove, and the groove in which the first filter portion 71 is received can be obtained without the need for etching or other processes. The surface of the first filter portion 71 away from the substrate 1 and the surface of the second encapsulation portion 632 away from the substrate 1 can be manufactured in the same reference plane by means of the groove.

In some other embodiments, the surface of the second encapsulation portion 632 away from the substrate 1 protrudes in the direction away from the substrate 1 relative to the surface of the first filter portion 71 away from the substrate 1. The display panel further includes a planarization layer 73. The planarization layer 73 covers the side of the first filter portion 71 away from the substrate 1, and the side of the first encapsulation portion 631 away from the substrate 1.

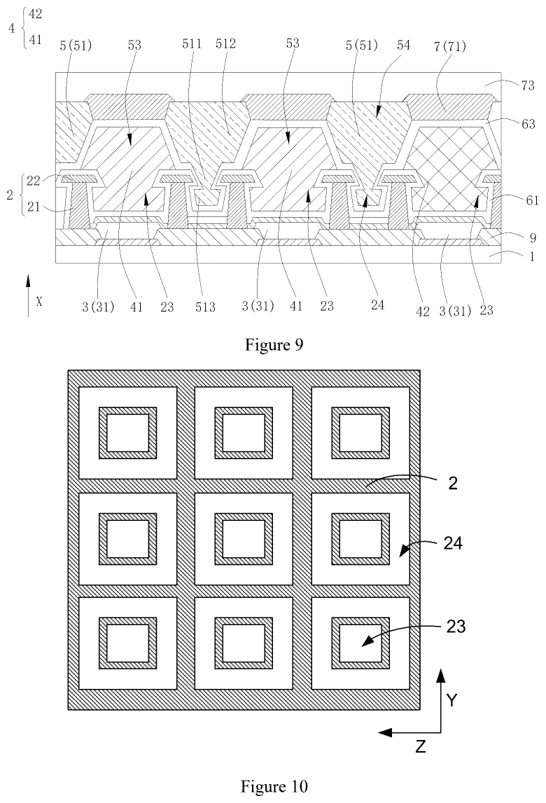

With reference to FIG. 9, in some embodiments, the isolation structure 2 defines a plurality of second isolation openings 24. At least part of each light-shielding unit 51 is disposed within the corresponding second isolation opening 24.

The second isolation openings 24 and the first isolation openings 23 may be arranged in a spaced manner, such that at least part of the light-shielding unit 51 disposed within the second isolation opening 24 is located between the light conversion units 41 disposed within the adjacent first isolation openings 23. At least part of the light-shielding unit 51 being disposed within the second isolation opening 24 increases the area of contact between the light-shielding unit 51 and the functional layer on the side thereof closer to the substrate 1, thereby reducing or preventing, to a certain extent, the separation of the light-shielding unit 51 from the adjacent functional layer.

With reference to FIG. 10, in some embodiments, an orthographic projection of the light-shielding layer 5 on the substrate 1 is mesh-like, and each second isolation opening 24 is disposed around the corresponding first isolation opening 23.

Since each second isolation opening 24 is disposed around the corresponding first isolation opening 23, the first isolation openings 23 can be separated by the second isolation openings 24, and the light conversion units 41 disposed within the first isolation openings 23 can be separated by the light-shielding layers 5 disposed within the second isolation openings 24. The light conversion units 41 may be arranged in an array in a second direction Y and a third direction Z, and the light conversion units 41 are located at mesh openings of the mesh-like light-shielding layer 5.

In some embodiments, the light-shielding unit 51 includes a first light-shielding portion 511 and a second light-shielding portion 512. The first light-shielding portion 511 is disposed on a side of the second light-shielding portion 512 close to the substrate 1. The first light-shielding portion 511 is disposed within the second isolation opening 24, and the second light-shielding portion 512 is located on a side of the second isolation opening 24 away from the substrate 1.

The first isolation opening 23 is defined by the first portion 21 and the second portion 22. The second portion 22 shields the first portion 21, and a wall surface of the first isolation opening 23 is configured to be non-planar, thereby increasing the surface area of the first light-shielding portion 511 opposing the isolation structure 2. In addition, since part of the light-shielding unit 51 is located within the first isolation opening 23, and another part thereof is located outside the first isolation opening 23, the separation of the light-shielding unit 51 from the functional layer located on the side thereof close to the substrate 1 is prevented to a certain extent.

In some embodiments, the orthographic projection of the second light-shielding portion 512 on the substrate 1 at least partially overlaps the orthographic projection of the isolation structure 2 on the substrate 1.

By the orthographic projection of the second light-shielding portion 512 on the substrate 1 at least partially overlapping the orthographic projection of the isolation structure 2 on the substrate 1, it is meant that at least part of a surface of the second light-shielding portion 512 close to the substrate 1 is disposed opposite the isolation structure 2 in the first direction X, thereby increasing the surface area of the second light-shielding portion 512 opposing the isolation structure 2, preventing or reducing, to a certain extent, the separation of the light conversion unit 41 from the functional layer located on the side thereof close to the substrate 1, and improving the product quality of the display panel.

In some embodiments, an orthographic projection of the first light-shielding portion 511 on the substrate 1 is located within the orthographic projection of the second light-shielding portion 512 on the substrate 1.

By configuring the orthographic projection of the first light-shielding portion 511 on the substrate 1 to be located within the orthographic projection of the second light-shielding portion 512 on the substrate 1, the second light-shielding portion 512 can form a cap structure with respect to the first light-shielding portion 511, to facilitate the fixation of the light-shielding unit 51 within the second isolation opening 24, thereby preventing, to a certain extent, the separation of the light-shielding unit 51 from the functional layer located on the side thereof close to the substrate 1, and improving the product quality of the display panel.

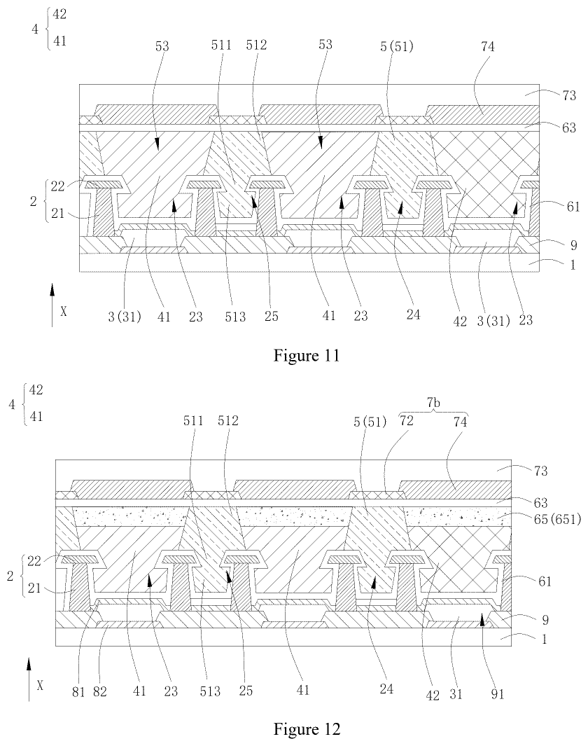

With reference to FIG. 11, in some embodiments, an orthographic projection on the substrate 1 of a surface of the second light-shielding portion 512 away from the substrate 1 is located within an orthographic projection on the substrate 1 of a surface of the second light-shielding portion 512 close to the substrate 1.

In the direction from the substrate 1 to the light-emitting unit 31, the size of the cross-section of the second conversion portion 412 may gradually increase, and the size of a cross-section of the second light-shielding portion 512 may gradually decrease. For example, the second conversion portion 412 has a trapezoidal cross-section, a length of a bottom base of the trapezoid close to the substrate 1 being less than a length of a top base of the trapezoid away from the substrate 1; and the second light-shielding portion 512 has a trapezoidal cross-section, a length of a bottom base of the trapezoid close to the substrate 1 being greater than a length of a top base of the trapezoid away from the substrate 1. By configuring the orthographic projection on the substrate 1 of the surface of the second light-shielding portion 512 away from the substrate 1 to be located within the orthographic projection on the substrate 1 of the surface of the second light-shielding portion 512 close to the substrate 1, an end of the second light-shielding portion 512 away from the substrate 1 can free up space for an end of the second conversion portion 412 away from the substrate 1, facilitating an increase in a light-emitting area of the second conversion portion 412. As a result, the emission of the converted light from the second conversion portion 412 is facilitated, improving the light conversion efficiency of the light conversion unit.

In some embodiments, the light-shielding unit 51 includes a third light-shielding portion 513. The third light-shielding portion 513 is disposed on a side of the first light-shielding portion 511 close to the substrate 1. The third light-shielding portion 513 is disposed within the second isolation opening 24. The orthographic projection of the first light-shielding portion 511 on the substrate 1 is located within the orthographic projection of the third light-shielding portion 513 on the substrate 1.

The orthographic projection of the first light-shielding portion 511 on the substrate 1 is located within the orthographic projection of the third light-shielding portion 513 on the substrate 1, and in the direction from the substrate 1 to the light-emitting unit 31, the part of the light-shielding unit 51 located within the second isolation opening 24 has a structure that is larger at the bottom and smaller at the top, and the disengagement of the light-shielding unit 51 from the second isolation opening 24 can thus be prevented to a certain extent.

When the orthographic projection of the first light-shielding portion 511 on the substrate 1 is located within the orthographic projection of the second light-shielding portion 512 on the substrate 1, the light-shielding unit 51 has a structure that is larger at two ends and smaller in the middle. The third light-shielding portion 513 can prevent the disengagement of the light-shielding unit 51 in the direction from the substrate 1 to the light-emitting functional layer 3, and the second light-shielding portion 512 can prevent the disengagement of the light-shielding unit 51 in the direction from the light-emitting functional layer 3 to the substrate 1.

In some embodiments, the orthographic projection of the third light-shielding portion 513 on the substrate 1 is located within the orthographic projection of the second light-shielding portion 512 on the substrate 1, such that the cross-sectional area of the third light-shielding portion 513 is less than the cross-sectional area of the second light-shielding portion 512, the third light-shielding portion 513 occupies a smaller space than the second light-shielding portion 512, and more space can thus be freed up and allocated to the isolation structure 2. The light-shielding unit 51 having a structure that is larger at two ends and smaller in the middle can effectively prevent the disengagement of the light-shielding unit 51 from the second isolation opening 24.

In some embodiments, the orthographic projection of the third light-shielding portion 513 on the substrate 1 overlaps the orthographic projection of the second portion 22 on the substrate 1.

The third light-shielding portion 513 may be located on the side of the second portion 22 close to the substrate 1. The third light-shielding portion 513 of the light-shielding unit 51 and the light conversion unit 41 that are adjacent to each other are separated by the first portion 21, and the second light-shielding portion 512 of the light-shielding unit 51 and the light conversion unit 41 that are adjacent to each other are separated by the second portion 22. The orthographic projection of the third light-shielding portion 513 on the substrate 1 overlaps the orthographic projection of the second portion 22 on the substrate 1, and the third light-shielding portion 513 can be restrained by the second portion 22, thereby preventing or reducing, to a certain extent, the disengagement of the light-shielding unit 51 from the second isolation opening 24. An edge of the third light-shielding portion 513 may be disposed opposite the second portion 22 in the first direction X.

In some embodiments, the area of the orthographic projection on the substrate 1 of the surface of the first portion 21 away from the substrate 1 is less than the area of the orthographic projection on the substrate 1 of the surface of the second portion 22 close to the substrate 1. The surface of the first portion 21 defining the first isolation opening 23 and the surface of the second portion 22 close to the substrate 1 define a recess 25. At least part of the third light-shielding portion 513 is located within the recess 25.

Since the area of the orthographic projection on the substrate 1 of the surface of the first portion 21 away from the substrate 1 is less than the area of the orthographic projection on the substrate 1 of the surface of the second portion 22 close to the substrate 1, the second portion 22 extends outward relative to the first portion 21 by a predetermined distance, a step is formed from the surface of the first portion 21 defining the first isolation opening 23 to the surface of the second portion 22 defining the first isolation opening 23, and the surface of the first portion 21 defining the first isolation opening 23 and the surface of the second portion 22 close to the substrate 1 define a recess 25. The recess 25 is an area that is recessed in a direction away from the center of the second isolation opening 24. During the manufacturing of the light-emitting unit 31, the light-emitting unit 31 has a large drop at an edge of the isolation structure 2, and the first portion 21 is recessed inward. As a result, the light-emitting units 31 are unlikely to be continuous on an outer side of the isolation structure 2, and accordingly breakage occurs, to form the light-emitting units 31 which are isolated from each other.

By configuring at least part of the third light-shielding portion 513 to be located within the recess 25, the third light-shielding portion 513 is prevented from disengaging from the second isolation opening 24.

With reference to FIG. 9, in some embodiments, the display panel further includes a third encapsulation layer 63. The light conversion layer 4 and the light-shielding layer 5 are disposed on a side of the third encapsulation layer 63 close to the substrate 1.

The third encapsulation layer 63 can encapsulate both the light conversion layer 4 and the light-shielding layer 5. In one embodiment, the orthographic projection of the third encapsulation layer 63 on the substrate 1 covers the orthographic projection of the light conversion layer 4 on the substrate 1 and the orthographic projection of the light-shielding layer 5 on the substrate 1.

In some embodiments, a surface of the light conversion layer 4 away from the substrate 1 and a surface of the light-shielding layer 5 away from the substrate 1 are in the same plane, thereby facilitating the manufacturing of a planar third encapsulation layer 63 on the light conversion layer 4 and the light-shielding layer 5, and reducing the occurrence of collapse or breakage of the third encapsulation layer 63.

With reference to FIG. 12, in some embodiments, the display panel further includes a fourth encapsulation layer 65. The fourth encapsulation layer 65 includes a plurality of fourth encapsulation portions 651. The fourth encapsulation portions 651 are located between the third encapsulation layer 63 and the light conversion layer 4.

Compared with the organic encapsulation layer, the inorganic encapsulation layer has better barrier performance against moisture and oxygen. Compared with the inorganic encapsulation layer, the organic encapsulation layer has better flexibility and film-forming properties. The light conversion layer 4 is encapsulated by both the fourth encapsulation portion 651 and the third encapsulation layer 63, thereby improving the overall barrier performance of the display panel against moisture and oxygen. In one embodiment, the fourth encapsulation portion 651 is located between adjacent light-shielding units 51.

In some embodiments, a surface of the fourth encapsulation layer 65 away from the substrate 1 is in the same reference plane as the surface of the light-shielding layer 5 away from the substrate 1.

Compared with the inorganic encapsulation layer, the organic encapsulation layer has better flexibility, enabling each fourth encapsulation portion 651 to planarize the light conversion unit 41 and the light-shielding unit 51, and the surface of the fourth encapsulation layer 65 away from the substrate 1 is planar, thereby facilitating the manufacturing of functional layers of required structures, such as the third encapsulation layer 63 and the filter layer 7.

In some embodiments, the display panel further includes a second filter layer 7. The second filter layer 7 includes a plurality of second filter portions 74. An orthographic projection of each second filter portion 74 on the substrate 1 at least partially overlaps the orthographic projection of the corresponding light conversion unit 41 on the substrate 1.

The second filter portion 74 may be formed with reference to the first filter portion 71 as described above. The orthographic projection of the second filter portion 74 on the substrate 1 at least partially overlaps the orthographic projection of the light conversion unit 41 on the substrate 1, and light emitted through the light conversion unit 41 can enter and then be emitted from the second filter portion 74.

In some embodiments, an area of an orthographic projection on the substrate 1 of a surface of the second filter portion 74 away from the substrate 1 is greater than an area of an orthographic projection on the substrate 1 of a surface of the second filter portion 74 close to the substrate 1.

An end of the second filter portion 74 away from the substrate 1 is larger than an end of the second filter portion 74 close to the substrate 1, thereby increasing the area through which light is emitted from the second filter portion 74.

In some embodiments, the second filter layer 7 further includes a plurality of light-blocking portions 72. The plurality of second filter portions 74 are spaced apart from each other, and part of each light-blocking portion 72 is located between adjacent second filter portions 74. An orthographic projection of each light-blocking portion 72 on the substrate 1 overlaps the orthographic projection of the corresponding light-shielding unit 51 on the substrate 1.

The light-blocking portion 72 may be made of the same light-shielding material as or a different light-shielding material from the light-shielding unit 51. The light-blocking portion 72 may be disposed between adjacent second filter portions 74 to shield them. The light-blocking portion 72 can shield light at a large angle, thereby alleviating the crosstalk problem of light emitted at a large angle between adjacent second filter portions 74. By the orthographic projection of the light-blocking portion 72 on the substrate 1 overlapping the orthographic projection of the light-shielding unit 51 on the substrate 1, it is meant that the light-blocking portion 72 is disposed on the side of the light-shielding unit 51 away from the substrate 1, thereby preventing or reducing, to a certain extent, the blocking of the light emitted from the light conversion unit 41 by the light-blocking portion 72.

In some embodiments, the orthographic projection of the light-blocking portion 72 on the substrate 1 is located within the orthographic projection of the light-shielding unit 51 on the substrate 1.

The light conversion unit 41 and the second filter portion 74 may be coaxially disposed, and the light-blocking portion 72 and the light-shielding unit 51 may be coaxially disposed. The orthographic projection of the light-blocking portion 72 on the substrate 1 is located within the orthographic projection of the light-shielding unit 51 on the substrate 1, thereby reducing the size of the light-blocking portion 72, increasing the size of the second filter portion 74, and increasing the area through which light can be emitted from the second filter layer 7.

In some embodiments, the second filter portion 74 protrudes in the direction away from the substrate 1 relative to a surface of the light-blocking portion 72 away from the substrate 1. An edge of the second filter portion 74 overlaps and is connected to the surface of the light-blocking portion 72 away from the substrate 1.

The second filter portion 74 protruding in the direction away from the substrate 1 relative to the surface of the light-blocking portion 72 away from the substrate 1 increases the area through which light is emitted from the second filter portion 74. The edge of the second filter portion 74 overlapping and being connected to the surface of the light-blocking portion 72 away from the substrate 1 increases the area of contact between the second filter portion 74 and the light-blocking portion 72, improving the relative stability of the two.

In some embodiments, at least part of the first portion 21 is located between adjacent light-emitting units 31, and the first portion 21 is a light-shielding member.

The first portion 21 may be made of an opaque material, and since at least part of the first portion 21 is located between adjacent light-emitting units 31, the light emitted from the adjacent light-emitting units 31 can be shielded by the first portion 21, thereby preventing or reducing, to a certain extent, the entrance of the light emitted from the light-emitting units 31 into the light conversion units 41 located within the adjacent first isolation openings 23.

In some embodiments, at least part of the first portion 21 is located between adjacent light conversion units 41, and the first portion 21 is a light-shielding member.

The first portion 21 may be made of an opaque material, and since at least part of the first portion 21 is located between adjacent light conversion units 41, the light emitted from the adjacent light conversion units 41 may be shielded by the first portion 21, thereby preventing or reducing, to a certain extent, the mixing of the light emitted from the light conversion units 41.

In some embodiments, the plurality of light conversion units 41 includes a plurality of color light conversion units 41. The light conversion layer 4 further includes a plurality of light modulation units 42. At least part of each light modulation unit 42 is disposed within the corresponding first isolation opening 23. The orthographic projections on the substrate 1 of the light conversion unit 41 and the light-emitting unit 31 located within the same first isolation opening 23 at least partially overlap each other. The light-emitting unit 31 is configured to emit a first color light. The color light conversion units 41 are configured to convert the incident first color light into a second color light. The light modulation units 42 are configured to transmit the first color light. A wavelength of the first color light and a wavelength of the second color light are different.

The first color light may be blue light, or may be blue light with a wavelength of 420 nm. The light modulation unit 42 and the light conversion unit 41 may have the same shape. The color light conversion unit 41 and the light modulation unit 42 have at least the following differences. After the first color light enters the color light conversion unit 41, the second color light is emitted, while after the first color light enters the light modulation unit 42, the first color light is emitted. In one embodiment, the second color light is red or green light.

In some embodiments, the color light conversion unit 41 includes quantum dot groups and a first photosensitive cross-linking group. The first photosensitive cross-linking group cross-links at least two of the quantum dot groups.

Quantum dots (QDs) are semiconductor nanocrystals with a radius less than or approximately equal to the exciton Bohr radius, and are a type of zero-dimensional nanomaterial. The quantum dots can be excited to produce fluorescence, and the quantum dots of different sizes can emit light of different colors. Therefore, after the light generated by the light-emitting unit 31 enters the color light conversion unit 41, the quantum dots can be excited to emit light of different colors.

The quantum dots may be selected from: Group II-VI quantum dots, such as CdS, CdSe, CdTe, ZnS, ZnSe, ZnTe, HgSe, HgTe, HgS, HgxCd₁₋ₓTe, HgxCd₁₋ₓS, HgxCd₁₋ₓSe, HgxZn₁₋ₓTe, CdxZn₁₋ₓSe, or CdxZn₁₋ₓS, where 0<x<1; Group III-V quantum dots, such as InP, InAs, InSb, GaAs, GaP, GaN, GaSb, InN, InSb, AlP, AlN, and AlAs; Group VI-VI quantum dots, such as PbS, PbSe, and PbTe; quantum dots of a core-shell structure, including CdSe@ZnS, CdSe@CdS, InP@ZnS, CdTe@CdSe, CdSe@ZnTe, ZnTe@CdSe, ZnSe@CdS, or Cd₁₋ₓZnxS@ZnS; ABX3-type perovskite quantum dots, where A is one or more of CH₃NH₃⁺ (methylammonium), NH₂CH═NH₂ (formamidinium), and Cs⁺, B is one or both of Pb²⁺ and Sn²⁺, and X is one or more of Cl⁻, Br⁻, and I⁻, including CH₃NH₃PbBr₃, CH₃NH₃PbCl₃, CH₃NH₃PbI₃, CsPbBr₃, CsPbCl₃, and CsPbI₃; or other types of quantum dots, such as CuInS₂, CuInSe₂, or AgInS₂.

The photosensitive cross-linking group is a group generated by a cross-linking reactant connecting quantum dot groups through a cross-linking reaction. The cross-linking reaction refers to a reaction in which two or more molecules are bonded and cross-linked to form a network structure. The cross-linking reactant can connect at least two quantum dot groups by undergoing a cross-linking reaction, thereby improving the stability of a plurality of quantum dot groups. The cross-linking reactant may be a reactant containing a carbon-carbon unsaturated bond, an isocyanate-based reactant, a diazide-based reactant, a reactant containing a ketone group, a halogen-containing Lewis acid, or a halogen-containing Lewis base.

A mixed material containing a cross-linking reactant and quantum dots can be used to form a patterned light-emitting functional layer 3 by a photolithography process. For example, a material layer is first formed using the mixed material. A mask having openings is used to expose a target region of the material layer, such that the quantum dot groups are cross-linked with first photosensitive cross-linking groups in the target region. The quantum dot groups in the target region form a network structure, and the stability of the material layer in the target region is higher than that of the material layer in a non-target region. The material layer is developed to remove the material layer from the non-target area, to obtain a patterned light conversion layer 4. The quantum dot groups in the light conversion layer 4 generate photogenerated carriers, i.e., electrons and holes, after being excited to emit light. When the electrons and holes recombine, photons are emitted, and the color light conversion unit 41 emits light in a color corresponding to the size of the quantum dot groups.

By way of example, when the cross-linking reactant is a cross-linking molecule, the cross-linking molecule and the quantum dots are mixed. Under the reaction conditions required for the cross-linking reaction, which may be irradiation with light waves of a preset wavelength, the cross-linking molecule is excited. The cross-linking molecule undergoes a cross-linking reaction to connect at least two quantum dot groups. A plurality of quantum dot groups form a network structure under the connection action of a plurality of cross-linking molecules.

By way of example, when the cross-linking reactant is a photosensitive cross-linking group, the photosensitive cross-linking group may be connected to the quantum dot groups through chemical bonds via ligands. Under the reaction conditions required for the cross-linking reaction, the photosensitive cross-linking group undergoes a cross-linking reaction to connect at least two quantum dot groups. The plurality of quantum dot groups form a network structure.

By configuring the color light conversion unit 41 to include the quantum dot groups and the first photosensitive cross-linking group, the color light conversion unit 41 can be manufactured by a photolithography process, thereby increasing the pixel density of the display panel. The color light conversion unit 41 being manufactured by a photolithography process can reduce or avoid the influence of the manufacturing process of the color light conversion unit 41 on the manufactured light-emitting units 31.

In some embodiments, the light modulation unit 42 includes scattering particles and a second photosensitive cross-linking group that cross-links at least two of the scattering particles.

The second photosensitive cross-linking group may be the same as, or different from, the first photosensitive cross-linking group. The scattering particles may be at least one of inorganic nanoparticles and organic nanoparticles, and the scattering particles can improve the light extraction efficiency from the light modulation unit 42. In one embodiment, the scattering particles are titanium oxide or zirconium oxide.

By configuring the color light conversion unit 41 to include the scattering particles and the second photosensitive cross-linking group, the light modulation unit 42 can be manufactured by a photolithography process to increase the pixel density of the display panel. The light modulation unit 42 being manufactured by a photolithography process can reduce or avoid the influence of the manufacturing process of the light modulation unit 42 on the manufactured light-emitting units 31.

In some embodiments, the red light conversion unit 41, the green light conversion unit 41, and the light modulation unit 42 are respectively located in three first isolation openings 23 and form a pixel light-emitting group. Pixel light-emitting groups are arranged in an array in the second direction Y and the third direction Z. The light-shielding layer 5 is mesh-like. The light-shielding units 51 are disposed to space the red light conversion unit 41 apart from the green light conversion unit 41, the red light conversion unit 41 apart from the light modulation unit 42, and the green light conversion unit 41 apart from the light modulation unit 42.

In some embodiments, the display panel further includes a first electrode layer. The first electrode layer is located on the side of the light-emitting unit 31 away from the substrate 1. The first electrode layer includes first electrodes 81 located within the first isolation openings 23. The first electrodes 81 are electrically connected to the isolation structure 2.

The first electrodes 81 may be cathodes or anodes. The first electrodes 81 are connected to the light-emitting units 31 to drive the light-emitting units 31 to emit light. The first electrodes 81 overlap and are connected to the isolation structure 2, and the isolation structure 2 can conduct and supply power to adjacent first electrodes 81, thereby forming a full-surface conductive planar electrode.

When the isolation structure 2 includes second isolation openings 24, the first electrode layer may further include an auxiliary electrode portion. The auxiliary electrode portion is located on the side of the light-shielding unit 51 away from the substrate 1. The auxiliary electrode portion is located within the second isolation openings 24. The auxiliary electrode portion is electrically connected to the isolation structure 2, and auxiliary electrodes can be electrically connected to the adjacent isolation structure 2.

When the display panel includes a first encapsulation layer 61, the first encapsulation layer 61 may be located on the side of the first electrode layer away from the substrate 1, and the first encapsulation layer 61 encapsulates the first electrode layer, thereby improving the operation stability of the first electrode layer.

In some embodiments, edges of the first electrodes 81 overlap and are connected to the first portion 21.

The first portion 21 may be entirely or partially made of a light-shielding metallic material, and the first portion 21 may serve as an electrically conductive structure electrically connected to the adjacent first electrode 81, or to the adjacent first electrode 81 and auxiliary electrode, and the first portion 21 may also serve as a light-shielding member to shield the light emitted from the adjacent light-emitting unit 31 and the adjacent light conversion unit 41.

In some embodiments, the display panel further includes a pixel defining layer 9 disposed between the substrate 1 and the isolation structure 2. The pixel defining layer 9 includes pixel openings 91. An orthographic projection of each of the pixel openings 91 on the substrate 1 is located within the orthographic projection of the corresponding first isolation opening 23 on the substrate 1.

The pixel defining layer 9 includes a pixel defining portion. The pixel defining portion defines the pixel openings 91. At least part of the light-emitting unit 31 may be disposed within the pixel opening 91 to achieve a light-emitting display of the display panel. The pixel openings 91 may be disposed in correspondence with the first isolation openings 23.

In some embodiments, the isolation structure 2 is disposed on a side of the pixel defining layer 9 away from the substrate 1, and at least part of each light-emitting unit 31 is disposed within the corresponding pixel opening 91.

The isolation structure 2 is disposed on the side of the pixel defining layer 9 away from the substrate 1, and an orthographic projection of the pixel opening 91 on the substrate 1 is located within the orthographic projection of the corresponding first isolation opening 23 on the substrate 1. The isolation structure 2 may be directly disposed on the side of the pixel defining layer 9 away from the substrate 1, and the isolation structure 2 is supported by means of the pixel defining layer 9. The orthographic projection of the pixel opening 91 on the substrate 1 may be located within the orthographic projection of the corresponding first isolation opening 23 on the substrate 1. The area of the first isolation opening 23 is greater than the area of the pixel opening 91, and the influence of the isolation structure 2 on a light-emitting viewing angle of the light-emitting functional layer 3 can be reduced.

In one embodiment, a plurality of pixel openings 91 are provided. The plurality of pixel openings 91 are distributed at intervals, and the isolation structure 2 may be disposed on at least part of the pixel defining portion between two adjacent pixel openings 91. In one embodiment, the isolation structure 2 may surround at least part of the pixel openings 91.

In some embodiments, the display panel further includes a second electrode layer. The second electrode layer is located on the side of the light-emitting units 31 close to the substrate 1. The second electrode layer includes second electrodes 82 located within the pixel openings 91.

One of the first electrode 81 and the second electrode 82 may serve as an anode electrode, and the other may serve as a cathode electrode. The first electrode 81, the light-emitting unit 31 and the second electrode 82 may be sequentially stacked in contact with one another to achieve an electrical connection between the first electrode 81, the light-emitting unit 31 and the second electrode 82. In one embodiment, the first electrode 81 serves as a cathode electrode, and the second electrode 82 serves as an anode electrode.

Each second electrode 82 may be insulated by the pixel defining portion, and the second electrodes 82 may be referred to as point electrodes distributed in an array.

In some embodiments, the orthographic projection of the light-shielding layer 5 on the substrate 1 is located within the orthographic projection of the pixel defining layer 9 on the substrate 1.

When the isolation structure 2 has the second isolation openings 24, the orthographic projections of the second isolation openings 24 on the substrate 1 fall within the orthographic projection of the pixel defining layer 9 on the substrate 1.

By configuring the orthographic projection of the light-shielding layer 5 on the substrate 1 to be located within the orthographic projection of the pixel defining layer 9 on the substrate 1, the influence of the isolation structure 2 on the light-emitting viewing angle of the light-emitting functional layer 3 is reduced.

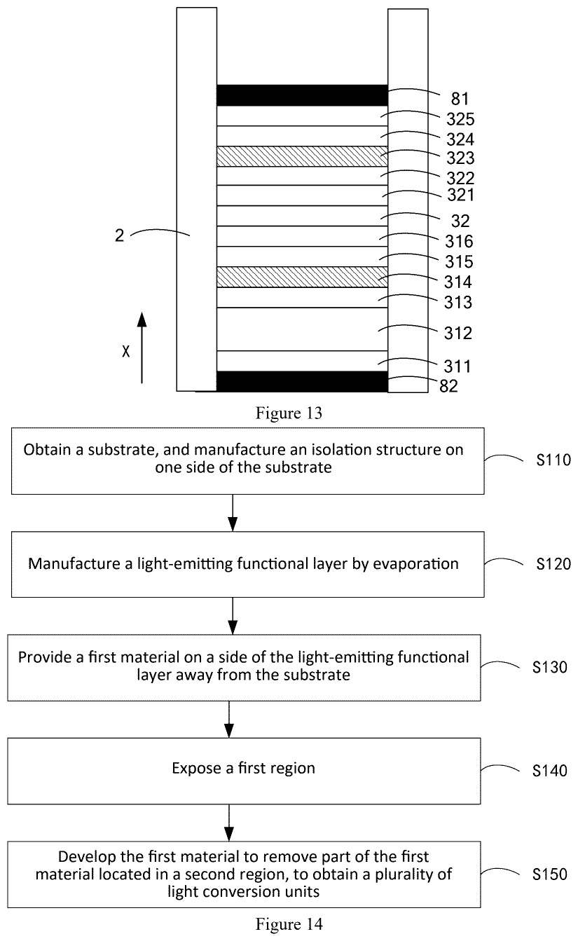

With reference to FIG. 13, the light-emitting unit may further include a first stacked structure, a charge generation layer (CGL) 32 and a second stacked structure that may form a stacked light-emitting structure. The charge generation layer 32 is disposed between the first stacked structure and the second stacked structure to supply electrons to one of the first stacked structure and the second stacked structure and to supply holes to the other. The first stacked structure may include a hole injection layer 311, a first hole transport layer 312, a first auxiliary light-emitting layer 313, a first light-emitting layer 314, a first hole blocking layer 315 and a first electron transport layer 316 that are sequentially stacked in the first direction X. The second stacked structure includes a second hole transport layer 321, a second auxiliary light-emitting layer 322, a second light-emitting layer 323, a second hole blocking layer 324 and a second electron transport layer 325 that are sequentially stacked in the first direction X. Quantum dots of different particle sizes may be provided in the light conversion units 41 as required, to convert incident color light by exciting the quantum dots.

In a second aspect, a display panel is provided, including a substrate 1, an isolation structure 2, a light-emitting functional layer 3, a light conversion layer 4, a first encapsulation layer 61 and a third encapsulation layer 63. The isolation structure 2 is disposed on a side of the substrate 1, and the isolation structure 2 defines a plurality of first isolation openings 23. The light-emitting functional layer 3 includes a plurality of light-emitting units 31. At least part of each light-emitting unit 31 is disposed within the corresponding first isolation opening 23. The light conversion layer 4 includes a plurality of light conversion units 41. Part of each light conversion unit 41 is located within the corresponding first isolation opening 23. The light-emitting functional layer 3 and the isolation structure 2 are disposed on the side of the first encapsulation layer 61 close to the substrate 1, and the light conversion layer 4 is disposed on the side of the first encapsulation layer 61 away from the substrate 1. The light conversion layer 4 is disposed on the side of the third encapsulation layer 63 close to the substrate 1.

The light conversion units 41 are disposed between the first encapsulation layer 61 and the third encapsulation layer 63, and the light conversion units 41 are encapsulated by the first encapsulation layer 61 and the third encapsulation layer 63, thereby preventing external moisture and oxygen from entering the light conversion units 41.

The display panel provided in the second aspect may include any embodiment of the display panel provided in the first aspect. Therefore, the display panel according to the embodiments in the second aspect of the present application also has the same advantageous effects as the display panel of any embodiment in the first aspect, which will not be repeated herein.

An embodiment of a third aspect of the present application also provides a method for manufacturing a display device. With reference to FIG. 14, the manufacturing method includes:
S110, obtaining a substrate 1, and manufacturing an isolation structure 2 on one side of the substrate 1, where the isolation structure 2 defines a plurality of first isolation openings 23;
S120, manufacturing a light-emitting functional layer 3 by means of the first isolation openings 23, where the light-emitting functional layer 3 includes a plurality of light-emitting units 31, at least part of each of the light-emitting units 31 being disposed within the corresponding first isolation opening 23;
S130, providing a first material layer on a side of the light-emitting functional layer 3 away from the substrate 1, where the first material layer includes quantum dots and a first cross-linking reactant, the first cross-linking reactant being a photosensitive cross-linking molecule or a photosensitive cross-linking group;
S140, expose a first region to cause the first cross-linking reactant to undergo a photo-cross-linking reaction to connect at least two quantum dots, where the first material layer includes the first region and a second region; and
S150, developing the first material layer to remove part of the first material layer located in the second region, to obtain a plurality of light conversion units 41, at least part of each of the light conversion units 41 being located within the corresponding first isolation opening 23.

The isolation structure 2 manufactured in step S120 includes a first portion 21 and a second portion 22 that are stacked. The first portion 21 is disposed on a side of the second portion 22 close to the substrate 1, and an orthographic projection of the first portion 21 on the substrate 1 is located within an orthographic projection of the second portion 22 on the substrate 1. A light-emitting material A used for manufacturing the light-emitting units 31 may cover the isolation structure 2 by means of evaporation technology. Since the second portion 22 shields the first portion 21, the light-emitting material A used for manufacturing the light-emitting units 31 has a large drop at an edge of the second portion 22, and it is unlikely to connect the light-emitting material A deposited into the first isolation opening 23 and the light-emitting material A deposited on the second portion 22. Accordingly, breakage occurs, and pieces of light-emitting material A spaced apart from each other are formed in adjacent first isolation openings 23. The light-emitting material A deposited on the second portion 22 may be removed as required.

Before step S130, the manufacturing method may further include:
S160, forming a first encapsulation layer 61 on the side of the light-emitting functional layer 3 away from the substrate 1.

In S130 to S150, the first material layer is disposed on the first encapsulation layer 61; a mask with openings is used to expose the first region of the first material layer to induce a cross-linking reaction between quantum dots and a first cross-linking reactant in a target region; and quantum dot groups in the target region form a network structure, and the stability of the material layer in the target region is higher than that of the material layer in a non-target region. The material layer is developed to remove the material layer from the second region, to obtain a patterned light conversion layer 4.

In the embodiment according to the present application, by configuring the first material layer to include the quantum dots and the first cross-linking reactant, the light conversion unit 41 can be manufactured by a photolithography process, thereby increasing the pixel density of the display panel. The light conversion unit 41 being manufactured by a photolithography process can reduce or avoid the influence of the manufacturing process of the light conversion unit 41 on the manufactured light-emitting units 31.

In some embodiments, after step S120, the manufacturing method includes:
S210, providing a light-shielding layer 5 on a side of the light-emitting functional layer 3 away from the substrate 1, where the light-shielding layer 5 includes a plurality of light-shielding units 51, at least part of each of the light-shielding units 51 being located between adjacent light conversion units 41.

The light-shielding layer 5 may be made of black resin. After manufacturing the light-emitting functional layer 3, the patterned light conversion layer 4 may be manufactured first as required, and the light-shielding unit 51 may be disposed between adjacent light conversion units 41. After manufacturing the light-emitting functional layer 3, the light-shielding layer 5 of a mesh structure may also be manufactured first as required, and the light conversion units 41 may be disposed within mesh openings of the light-shielding layer 5. The present application does not limit the manufacturing sequence of the light-shielding units 51 and the light conversion units 41.

When the display panel is provided with a third encapsulation layer 63, the manufacturing sequence of the third encapsulation layer 63 and the light-shielding units 51 may also be determined according to the relative positions of the third encapsulation layer 63 and the light-shielding units 51.

In some embodiments, after step S210, the manufacturing method further includes:
310, providing a filter layer 7 on the side of the light-emitting functional layer 3 away from the substrate 1, where the filter layer 7 includes a plurality of first filter portions 71 spaced apart from each other, part of each of the light-shielding units 51 being located between adjacent first filter portions 71.

Part of the light-shielding unit 51 may be configured to protrude from the light conversion unit in a direction away from the substrate 1, and the part of the light-shielding unit 51 can be disposed between adjacent first filter portions 71, and the portion of the light-shielding unit 51 is also used for shielding between the adjacent first filter portions 71. Compared with the solution where a light-shielding member is provided between adjacent light conversion units 41 using one mask and another light-shielding member is provided between adjacent first filter portions 71 using another mask, part of the light-shielding unit 51 being located between adjacent first filter portions 71 enables at least one step of manufacturing a light-shielding member using a mask to be omitted, thereby simplifying the manufacturing process.

An embodiment of a fourth aspect of the present application further provides a display device, including a display panel according to any embodiment of the first aspect, the display panel according to any embodiment of the second aspect, or the display panel manufactured by the method for manufacturing a display panel according to any embodiment of the third aspect. Since the display device provided in the embodiment of the fourth aspect of the present application includes the display panel according to any embodiment of the first aspect, the second aspect, or the third aspect, the display device provided in the embodiment of the fourth aspect has the advantageous effects as the display panel of any embodiment described above, which will not be repeated again herein.

The display device in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, and good use of the present application and modify and use the present application may be made. The present application is limited only by the claims and all the scopes and equivalents thereof.

What is claimed is:

1. A display panel, comprising:
a substrate;
an isolation structure disposed on one side of the substrate and defining a plurality of first isolation openings;
a light-emitting functional layer comprising a plurality of light-emitting units, at least part of each of the light-emitting units being disposed within the corresponding first isolation opening; and
a light conversion layer comprising a plurality of light conversion units, an orthographic projection of each of the light conversion units on the substrate at least partially overlapping an orthographic projection of the corresponding light-emitting unit on the substrate, and at least part of the light conversion unit being disposed within the corresponding first isolation opening.

2. The display panel according to claim 1, further comprising:
a first encapsulation layer disposed on a side of the light-emitting functional layer and the isolation structure away from the substrate, wherein an orthographic projection of the first encapsulation layer on the substrate covers at least part of the orthographic projections of the light-emitting units on the substrate, and the light conversion layer is disposed on a side of the first encapsulation layer away from the substrate; and
the light conversion layer is in direct contact with the first encapsulation layer.

3. The display panel according to claim 2, further comprising:
a second encapsulation layer disposed between the light conversion layer and the first encapsulation layer, wherein the light conversion layer is in direct contact with the second encapsulation layer;
the second encapsulation layer comprises a plurality of second encapsulation portions located within the first isolation openings and between the first encapsulation layer and the light conversion unit;
the first encapsulation layer is an inorganic encapsulation layer; and
the second encapsulation layer is an organic encapsulation layer.

4. The display panel according to claim 1, wherein each of the light conversion units comprises a first conversion portion located within the corresponding first isolation opening;
each of the light conversion units comprises a second conversion portion stacked on a side of the first conversion portion away from the substrate and located outside the corresponding first isolation opening;
the orthographic projection of each of the light-emitting units on the substrate is located within the orthographic projection of the corresponding light conversion unit on the substrate;
an orthographic projection of the second conversion portion on the substrate at least partially overlaps an orthographic projection of the isolation structure on the substrate;
an orthographic projection on the substrate of a surface of the second conversion portion close to the substrate is located within an orthographic projection on the substrate of a surface of the second conversion portion away from the substrate; and
an orthographic projection of the first conversion portion on the substrate is located within the orthographic projection of the corresponding second conversion portion on the substrate.

5. The display panel according to claim 4, wherein each of the light conversion units comprises a third conversion portion disposed on a side of the first conversion portion close to the substrate, the third conversion portion being disposed within the corresponding first isolation opening, and the orthographic projection of the first conversion portion on the substrate is located within an orthographic projection of the third conversion portion on the substrate;
the orthographic projection of the third conversion portion on the substrate is located within the orthographic projection of the corresponding second conversion portion on the substrate;
the isolation structure comprises a first portion and a second portion, the first portion and the second portion being stacked, the first portion being disposed on a side of the second portion close to the substrate, and an orthographic projection of the first portion on the substrate being located within an orthographic projection of the second portion on the substrate;
the third conversion portion is located on a side of the second portion close to the substrate, and the orthographic projection of the third conversion portion on the substrate overlaps the orthographic projection of the second portion on the substrate; and
an area of an orthographic projection on the substrate of a surface of the first portion away from the substrate is less than an area of an orthographic projection on the substrate of a surface of the second portion close to the substrate, and a surface of the first portion defining the first isolation opening and a surface of the second portion close to the substrate define a recess, at least part of the third conversion portion being located within the recess.

6. The display panel according to claim 1, further comprising:
a light-shielding layer comprising a plurality of light-shielding units, at least part of each of the light-shielding units defining a first opening, the first opening being in communication with the corresponding first isolation opening, and at least part of the light conversion unit being located within the first opening;
an orthographic projection of the first opening on the substrate overlaps an orthographic projection of the corresponding first isolation opening on the substrate;
an orthographic projection of each of the light-shielding units on the substrate at least partially overlaps an orthographic projection of the isolation structure on the substrate;
the orthographic projection of the first isolation opening on the substrate is located within the orthographic projection of the first opening on the substrate;
the orthographic projection of the first opening on the substrate is located within the orthographic projection of the first isolation opening on the substrate;
the orthographic projections of the light-shielding units on the substrate cover the orthographic projection of the isolation structure on the substrate, and part of each of the light-shielding units is disposed within the corresponding first isolation opening;
each of the light-shielding units comprises a first light-shielding portion and a second light-shielding portion; the first light-shielding portion is disposed on a side of the second light-shielding portion close to the substrate and within the corresponding first isolation opening, and the second light-shielding portion is located on a side of the first isolation opening away from the substrate;
an orthographic projection on the substrate of a surface of the second light-shielding portion close to the substrate at least partially overlaps the orthographic projection of the isolation structure on the substrate;
each of the light-shielding units has a receiving cavity, and at least part of the isolation structure is received within the receiving cavity;
the same light-shielding unit is located within adjacent first isolation openings, respectively; and
the first light-shielding portions located within the same first isolation opening surround the corresponding light conversion unit.

7. The display panel according to claim 6, wherein at least part of each of the light-shielding units defines a second opening, the first opening being in communication with the second opening;
the display panel further comprises:
a first filter layer comprising a plurality of first filter portions, wherein the first filter portions are disposed on a side of the light conversion units away from the substrate, and at least part of each of the first filter portions is disposed within the corresponding second opening;
an orthographic projection of each of the first filter portions on the substrate at least partially overlaps the orthographic projection of the corresponding light conversion unit on the substrate;
an area of an orthographic projection on the substrate of a surface of each of the first filter portions away from the substrate is greater than an area of an orthographic projection on the substrate of a surface of the first filter portion close to the substrate; and
the display panel comprises:
a third encapsulation layer located between the first filter portions and the light conversion units.

8. The display panel according to claim 7, wherein the light-shielding units are located on a side of the third encapsulation layer away from the substrate;
the third encapsulation layer is disposed to space the light-shielding units apart from the light conversion units;
the plurality of the first filter portions are spaced apart from each other, and part of each of the light-shielding units is located between adjacent first filter portions; and
each of the first filter portions protrudes in a direction away from the substrate relative to a surface of the corresponding light-shielding unit away from the substrate, and an edge of the first filter portion overlaps and is connected to the surface of the light-shielding unit away from the substrate.

9. The display panel according to claim 8, wherein the light-shielding units are located on a side of the third encapsulation layer close to the substrate; and
the third encapsulation layer is disposed to space the light-shielding units from the first filter portions.

10. The display panel according to claim 6, wherein the isolation structure defines a plurality of second isolation openings, and at least part of each of the light-shielding units is disposed within the corresponding second isolation opening;
an orthographic projection of the light-shielding layer on the substrate is mesh-like, and each of the second isolation openings is disposed around the corresponding first isolation opening;
each of the light-shielding units comprises a first light-shielding portion and a second light-shielding portion; the first light-shielding portion is disposed on a side of the second light-shielding portion close to the substrate and within the corresponding second isolation opening, and the second light-shielding portion is located on a side of the second isolation opening away from the substrate;
an orthographic projection of the second light-shielding portion on the substrate at least partially overlaps the orthographic projection of the isolation structure on the substrate;
an orthographic projection of the first light-shielding portion on the substrate is located within the orthographic projection of the second light-shielding portion on the substrate; and
an orthographic projection on the substrate of a surface of the second light-shielding portion away from the substrate is located within an orthographic projection on the substrate of a surface of the second light-shielding portion close to the substrate.

11. The display panel according to claim 10, wherein each of the light-shielding units comprises a third light-shielding portion disposed on a side of the first light-shielding portion close to the substrate, the third light-shielding portion being disposed within the corresponding second isolation opening, and the orthographic projection of the first light-shielding portion on the substrate is located within an orthographic projection of the third light-shielding portion on the substrate;
the orthographic projection of the third light-shielding portion on the substrate is located within the orthographic projection of the corresponding second light-shielding portion on the substrate;
the isolation structure comprises a first portion and a second portion, the first portion and the second portion being stacked, the first portion being disposed on a side of the second portion close to the substrate, an orthographic projection of the first portion on the substrate being located within an orthographic projection of the second portion on the substrate, and the orthographic projection of the third light-shielding portion on the substrate overlapping the orthographic projection of the second portion on the substrate; and
an area of an orthographic projection on the substrate of a surface of the first portion away from the substrate is less than an area of an orthographic projection on the substrate of a surface of the second portion close to the substrate, and an end of the first portion away from the substrate and an end of the second portion close to the substrate form a recess, at least part of the third light-shielding portion being located within the recess.

12. The display panel according to claim 6, further comprising:
a third encapsulation layer, wherein the light conversion layer and the light-shielding layer are disposed on a side of the third encapsulation layer close to the substrate;
a surface of the light conversion layer away from the substrate and a surface of the light-shielding layer away from the substrate are in the same plane; and
the display panel further comprises:
a fourth encapsulation layer comprising a plurality of fourth encapsulation portions located between the third encapsulation layer and the light conversion units,
surface of the fourth encapsulation layer away from the substrate is in the same reference plane as the surface of the light-shielding layer away from the substrate.

13. The display panel according to claim 6, further comprising:
a second filter layer comprising a plurality of second filter portions, wherein an orthographic projection of each of the second filter portions on the substrate at least partially overlaps the orthographic projection of the corresponding light conversion unit on the substrate;
an area of an orthographic projection on the substrate of a surface of each of the second filter portions away from the substrate is greater than an area of an orthographic projection on the substrate of a surface of the second filter portion close to the substrate;
the second filter layer further comprises a plurality of light-blocking portions, the plurality of the second filter portions are spaced apart from each other, part of each of the light-blocking portion is located between adjacent second filter portions, and an orthographic projection of each of the light-blocking portions on the substrate overlaps an orthographic projection of the corresponding light-shielding unit on the substrate; and
each of the second filter portions protrudes in a direction away from the substrate relative to a surface of the corresponding light-blocking portion away from the substrate, and an edge of the second filter portion overlaps and is connected to the surface of the light-blocking portion away from the substrate.

14. The display panel according to claim 1, wherein the isolation structure comprises a first portion and a second portion, the first portion and the second portion being stacked, the first portion being disposed on a side of the second portion close to the substrate, and an orthographic projection of the first portion on the substrate being located within an orthographic projection of the second portion on the substrate;
at least part of the first portion is located between adjacent light-emitting units, and the first portion serves as a light-shielding member;
or at least part of the first portion is located between adjacent light conversion units, and the first portion serves as a light-shielding member.

15. The display panel according to claim 1, wherein the plurality of light conversion units comprise a plurality of color light conversion units; the light conversion layer further comprises a plurality of light modulation units, at least part of each of the light modulation units being disposed within the corresponding first isolation opening;
orthographic projections of the light conversion unit and the light-emitting unit located within the same first isolation opening on the substrate at least partially overlap each other, the light-emitting unit is configured to emit a first color light, the color light conversion units are configured to convert the incident first color light into a second color light, the light modulation units are configured to transmit the first color light, and a wavelength of the first color light and a wavelength of the second color light are different.

16. The display panel according to claim 15, wherein each of the color light conversion units comprises quantum dot groups and a first photosensitive cross-linking group, the first photosensitive cross-linking group cross-linking at least two of the quantum dot groups; and
each of the light modulation units comprises scattering particles and a second photosensitive cross-linking group, the second photosensitive cross-linking group cross-linking at least two of the scattering particles.

17. The display panel according to claim 1, further comprising:
a first electrode layer located on a side of the light-emitting units away from the substrate, wherein the first electrode layer comprises first electrodes located within the first isolation openings, the first electrodes being electrically connected to the isolation structure; and
the isolation structure comprises a first portion and a second portion, the first portion and the second portion being stacked, the first portion being disposed on a side of the second portion close to the substrate, an orthographic projection of the first portion on the substrate being located within an orthographic projection of the second portion on the substrate, and edges of the first electrodes overlapping and being connected to the first portion.

18. The display panel according to claim 1, further comprising:
a pixel defining layer disposed between the substrate and the isolation structure, wherein the pixel defining layer comprises pixel openings, an orthographic projection of each of the pixel openings on the substrate being located within an orthographic projection of the corresponding first isolation opening on the substrate;
the isolation structure is disposed on a side of the pixel defining layer away from the substrate, and at least part of each of the light-emitting units is disposed within the corresponding pixel opening;
the display panel further comprises:
a second electrode layer located on a side of the light-emitting units close to the substrate, the second electrode layer comprising second electrodes located within the pixel openings; and
the display panel further comprises a light-shielding layer, an orthographic projection of the light-shielding layer on the substrate being located within an orthographic projection of the pixel defining layer on the substrate.

19. A display panel, comprising:
a substrate;
an isolation structure disposed on one side of the substrate, wherein the isolation structure defines a plurality of first isolation openings, and the isolation structure comprises a first portion and a second portion, the first portion and the second portion being stacked, the first portion being disposed on a side of the second portion close to the substrate, and an orthographic projection of the first portion on the substrate being located within an orthographic projection of the second portion on the substrate;
a light-emitting functional layer comprising a plurality of light-emitting units, at least part of each of the light-emitting units being disposed within the corresponding first isolation opening;
a light conversion layer comprising a plurality of light conversion units, at least part of each of the light conversion units being located within the corresponding first isolation opening;
a first encapsulation layer, wherein the light-emitting functional layer and the isolation structure are disposed on a side of the first encapsulation layer close to the substrate, and the light conversion layer is disposed on a side of the first encapsulation layer away from the substrate; and
a third encapsulation layer, wherein the light conversion layer is disposed on a side of the third encapsulation layer close to the substrate.

20. A display device, comprising:
a display panel, comprising:
a substrate;
an isolation structure disposed on one side of the substrate and defining a plurality of first isolation openings;
a light-emitting functional layer comprising a plurality of light-emitting units, at least part of each of the light-emitting units being disposed within the corresponding first isolation opening; and
a light conversion layer comprising a plurality of light conversion units, an orthographic projection of each of the light conversion units on the substrate at least partially overlapping an orthographic projection of the corresponding light-emitting unit on the substrate, and at least part of the light conversion unit being disposed within the corresponding first isolation opening.
